(19) United States
(12) Patent Application Publication
(10) Pub. No.: US 2020/0255970 A1
(43) Pub. Date: Aug. 13, 2020

(54) DRAFT TUBE OF CRYSTAL GROWING FURNACE AND THE CRYSTAL GROWING FURNACE

(71) Applicant: ZING SEMICONDUCTOR CORPORATION, Shanghai (CN)

(72) Inventors: Weimin Shen, Shanghai (CN); Gang Wang, Shanghai (CN); Xianliang Deng, Shanghai (CN); Wee Teck Tan, Shanghai (CN); Hanyi Huang, Shanghai (CN)

(21) Appl. No.: 16/702,443

(22) Filed: Dec. 3, 2019

(30) Foreign Application Priority Data
Dec. 4, 2018 (CN) 201811472539.1

(51) Int. Cl. C30B 15/00; C30B 29/06

(52) U.S. Cl. CPC C30B 15/00; C30B 29/06

(57) ABSTRACT

The present application provides a draft tube of crystal growing furnace and the crystal growing furnace. The draft tube comprises an inner tube, an outer tube and a thermal insulating material sandwiched between the inner tube and the outer tube, wherein the inner tube has a thermal resistance lower than that of the outer tube. Accordingly, the outer tube having the higher thermal resistance reduces the heat transfer from the outer tube to the inner tube, thereby the temperature of the inner tube can be reduced, the heat radiation from the ingot surface to the inner tube can be enhanced, and the vertical temperature gradient of the ingot can be increased. At the same time, the temperature of the outer tube increases to reduce the condensation of silica vapor (SiOx) evaporated from the silicon melt surface, thereby impurity formation and dislocation defect caused by the SiOx fallen into the silicon melt can be prevented.

### BACKGROUND OF THE INVENTION

### 1. Field of the Invention

The present invention relates to the manufacture of semiconductors and the manufacture of the mono-crystalline silicon for photovoltaic applications, and more particularly to a draft tube of a crystal growing furnace and the crystal growing furnace.

### 2. Description of the Related Art

Czochralski method is widely and generally applied for manufacture of mono-crystalline silicon. With continued development of the semiconductor industry, in order to reduce cost, the process efficiency is further requested based on the equivalent product quality. One direct way to increase the process efficiency is to increase the growth rate of body of the crystal ingot and shorten the crystal-pulling time. In the practical manufacture, first, the vertical temperature gradient of the ingot should be increased to release latent heat of the crystal more rapidly, then the axis temperature gradient of the melt at the crystallization interface should be decreased. Therefore, the target of the manufacture to enhance the growth rate of the crystal body and shorten the crystal-pulling time can be achieved accordingly.

A solution for increasing the vertical temperature gradient of the ingot is to dispose a draft tube along with the direction of crystal growth, thereby the heat radiation from the crucible and the silicon melt to the crystal surface can be prevented and the vertical temperature gradient of the ingot can be increased. At the same time, the draft tube conducts an inert gas introduced from the upper part of the crystal growing furnace to pass through the surface of the silicon melt with higher flow speed, so that the contents of oxygen and impurities within the crystal can be controlled.

A typical structure of a draft tube contains an inner tube, an outer tube and a thermal insulating material disposed between the inner tube and the outer tube, the thickness of the inner tube is less than that of the outer tube to guarantee the strength of the draft tube. However, with the development of larger size of wafer, the thermal insulating effect of the current draft tube cannot satisfy the requirement of the vertical temperature gradient of the crystal ingot.

Therefore, there is a need for a novel draft tube of a crystal growing furnace and the novel crystal growing furnace that can solve problems existed in current technologies.

### SUMMARY

In the summary of the invention, a series of concepts in a simplified form is introduced, which will be described in further detail in the detailed description. This summary of the present invention does not intend to limit the key elements or the essential technical features of the claimed technical solutions, nor intend to limit the scope of the claimed technical solution.

The present application provides a draft tube of a crystal growing furnace comprising an inner tube, an outer tube and a thermal insulating material sandwiched between the inner tube and the outer tube, wherein the inner tube has a thermal resistance less than that of the outer tube.

The present application also provides a crystal growing furnace comprising a draft tube as defined in the present application.

### BRIEF DESCRIPTION OF THE DRAWINGS

FIG. 1 illustrates a structure diagram of the crystal growing furnace in accordance with one embodiment of the present application.

FIG. 2 illustrates a structure diagram of the draft tube of the crystal growing furnace in accordance with one embodiment of the present application.

FIG. 3A illustrates the temperature distribution on the inner tube of the known draft tube based on analog calculation, and FIG. 3B illustrates the temperature distribution on the inner tube of the draft tube of FIG. 2 based on analog calculation.

FIG. 4 illustrates a structure diagram of the draft tube of the crystal growing furnace in accordance with one embodiment of the present application.

### DETAILED DESCRIPTION OF THE EMBODIMENTS

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

For a thorough understanding of the present invention, the detailed steps will be set forth in detail in the following description in order to explain the the draft tube of the crystal growing furnace and the crystal growing furnace of the present invention. The preferred embodiments of the present invention is described in detail as follows, however, in addition to the detailed description, the present invention also may have other embodiments.

The terminology used herein is for the purpose of describing particular example embodiments only and is not intended to be limiting. As used herein, the singular forms may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

It should be understood that the present invention may be practiced in different forms and that neither should be construed to limit the scope of the disclosed examples. On the contrary, the examples are provided to achieve a full and complete disclosure and make those skilled in the art fully receive the scope of the present invention. In the drawings, for clarity purpose, the size and the relative size of layers and areas may be exaggerated. In the drawings, same reference number indicates same element.

To solve the problems existed in current technologies, the present application provides a draft tube of a crystal growing furnace comprising an inner tube, an outer tube and a thermal insulating material sandwiched between the inner tube and the outer tube, wherein the inner tube has a thermal resistance less than that of the outer tube.

In one embodiment, the ratio of the wall thickness of the outer tube to the wall thickness of the inner tube is more than 0, and less than or equal to 1. Namely, 0<wall thickness of outer tube/inner tube 1.

In one embodiment, the ratio of the wall thickness of the outer tube to that of the inner tube is less than 1 and more than 0, and the outer tube and the inner tube are formed by the same material.

In one embodiment, the outer tube and the inner tube are formed by a graphite material.

In one embodiment, the inner tube has the wall thickness of 10 mm-14 mm, and the outer tube has the wall thickness of 6 mm-10 mm.

In one embodiment, the outer tube and the inner tube are formed by different materials, and the inner tube has a thermal conductivity higher than that of the outer tube.

In one embodiment, the inner tube is formed by a first graphite material, and the outer tube is formed by a second graphite material or a ceramic material, wherein the second graphite material or the ceramic material has a thermal conductivity less than that of the first graphite material.

In one embodiment, the thermal insulating material comprises glass fiber, asbestos, rock wool, soft felt or vacuum layer.

The present application further provides a crystal growing furnace comprising a draft tube as defined above.

According to the draft tube and the crystal growing furnace of the present application, the draft tube comprises an inner tube, an outer tube and a thermal insulating material sandwiched between the inner tube and the outer tube, wherein the outer tube has a thermal resistance higher than that of the inner tube. The outer tube having the higher thermal resistance reduces the heat transfer from the outer tube to the inner tube, thereby the temperature of the inner tube can be reduced, the heat radiation from the ingot surface to the inner tube can be enhanced, and the vertical temperature gradient of the ingot can be increased. At the same time, the temperature of the outer tube increases to reduce the condensation of silica vapor (SiOx) evaporated from the silicon melt surface, thereby impurity formation and dislocation defect caused by the SiOx fallen into the silicon melt can be prevented.

### EXAMPLES

### Example 1

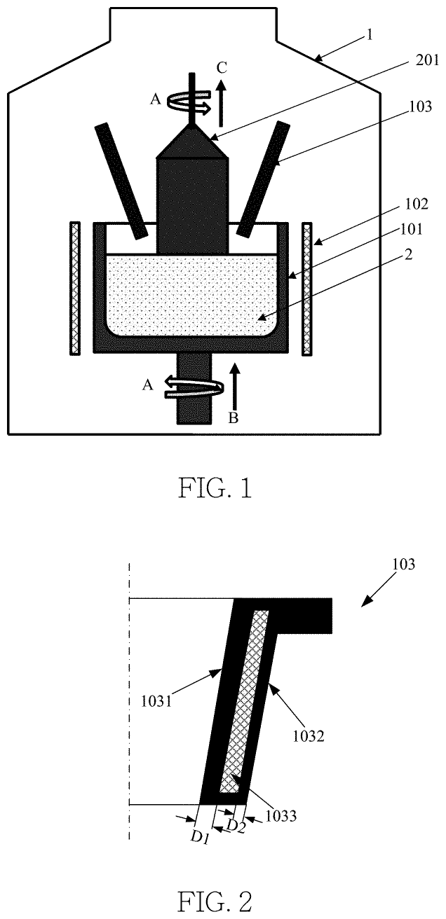

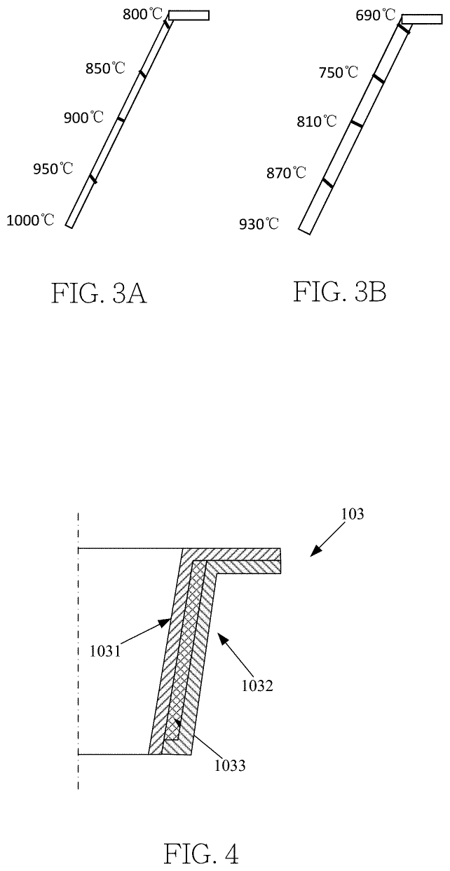

Referring FIG. 1, FIG. 2 and FIG. 3, the draft tube of the crystal growing furnace and the crystal growing furnace are explained hereafter. FIG. 1 illustrates a structure diagram of the crystal growing furnace in accordance with one embodiment of the present application. FIG. 2 illustrates a structure diagram of the draft tube of the crystal growing furnace in accordance with one embodiment of the present application. FIG. 3 illustrates the temperature distribution on the inner tube of the draft tube based on analog calculation, in which FIG. 3A is the draft tube of prior art and FIG. 3B is the draft tube of FIG. 2.

Czochralski method (briefly “CZ method”) is the most widely applied for manufacture of mono-crystalline silicon of silicon wafer. In CZ method, a crystal seed is immersed in silicon melt contained in a quartz crucible, then is pulled to grow mono-crystalline silicon thereon. The crystal ingot obtained by applying CZ method is sliced to form silicon wafers. A typical structure of a crystal growing furnace is shown in FIG. 1. The crystal growing furnace comprises a furnace body 1, a crucible 101 and a heater 102 disposed in the furnace body 1, wherein the heater 102 heats the crucible 101. A crucible driving device (not shown) is disposed under the crucible 101 to drive rotation and vertical movement of the crucible 101, and the direction of rotation and vertical movement is respectively indicated by the arrow A and the arrow B in FIG. 1. During the crystal pulling, a silicon melt 2 is contained in the crucible 101, and a lifting device (not shown) disposed at the top of the furnace body pulls the ingot 201 to move upward, as indicated by the arrow C in FIG. 1, to grow the crystal.

During the crystal growth, with the crystal formation of the ingot 201, the larger temperature gradient along with the axis of the ingot 201 benefits release of latent heat of the crystal. As shown in FIG. 1, a draft tube 103 is disposed surrounding the ingot 201. The draft tube 103 prevents the heat radiation from the silicon melt 2 in the crucible 101 to the ingot 201 and benefits the increase of the vertical temperature gradient of the ingot 201. Moreover, an inert gas is introduced from the upper part of the furnace body 1 to prevent oxidation of silicon melt and silicon ingot, and the draft tube is able to conduct the inert gas.

The draft tube 103 of the present application has a cone-shaped tube structure with two open terminals, and in the cone-shaped tube structure, the diameter of the bottom is smaller than that of the top. The draft tube 103 comprises an inner tube, an outer tube and a thermal insulating material sandwiched between the inner tube and the outer tube.

Referring FIG. 2, the sectional view of side wall of the draft tube in accordance with one embodiment of the present application is illustrated. The draft tube 103 comprises an inner tube 1031, an outer tube 1032 and a thermal insulating material 1033 sandwiched between the inner tube 1031 and the outer tube 1032. The outer tube 1032 has a thermal resistance larger than that of the inner tube 1031. Therefore, the outer tube 1032 having the higher thermal resistance reduces the heat transfer from the outer tube to the inner tube, thereby the temperature of the inner tube can be reduced, the heat radiation from the ingot surface to the inner tube of the draft tube can be enhanced, and the vertical temperature gradient of the ingot can be increased. At the same time, the temperature of the outer tube increases to reduce the condensation of silica vapor (SiOx) evaporated from the silicon melt surface, thereby impurity formation and dislocation defect caused by the SiOx fallen into the silicon melt can be prevented.

In one embodiment, the thermal insulating material comprises glass fiber, asbestos, rock wool, soft felt, vacuum layer and the like. In one example, the thermal insulating material is a vacuum chamber disposed between the inner tube and the outer tube to minimize the heat transfer between the outer tube and the inner tube.

In one embodiment, the outer tube and the inner tube are formed by the same material, such as graphite material or carbon-carbon composite material, and the wall thickness of the inner tube is larger than that of the outer tube. As shown in FIG. 2, the wall thickness D1 of the inner tube 1031 is larger than the wall thickness D2 of the outer tube 1032. Because the outer tube 1032 and the inner tube 1031 are formed by the same material, the thermal conductivity of the inner tube 1031 is better than that of the outer tube 1032, namely, the less heat is transferred from the outer tube 1032 to the inner tube 1031. Comparing with the situation that the inner tube 1031 has a wall thinner than the outer tube 1032, the present embodiment effectively decreases the temperature of the inner tube, thereby the heat radiation from the ingot 201 surface to the inner tube 1031 can be enhanced, and the vertical temperature gradient of the ingot 201 can be increased. At the same time, the temperature of the outer tube 1032 increases to reduce the condensation of silica vapor (SiOx) evaporated from the silicon melt surface, thereby impurity formation and dislocation defect caused by the SiOx fallen from the outer tube 1032 into the silicon melt can be reduced.

In one embodiment, the outer tube and the inner tube are formed by a graphite material. Because the graphite material has good strength at high temperature, it is able to guarantee the strength of the draft tube even the outer tube wall becomes thinner and the inner tube wall becomes thicker.

In one embodiment, the inner tube has the wall thickness of 10 mm-14 mm, and the outer tube has the wall thickness of 6 mm-10 mm. While the wall thickness of the inner tube and the outer tube is respectively set as 10-14 mm and 6-10 mm and the inner tube wall is thicker than the outer tube wall, the outer tube is able to maintain its heat dissipation efficiency and the draft tube is not overweight. In one example, the inner tube has the wall thickness of 12 mm and the outer tube has the wall thickness of 8 mm.

Referring FIGS. 3A and 3B, the temperature distribution on the inner tubes of prior art and FIG. 2 are shown. In FIG. 3A, a well-known draft tube with an inner tube having a wall thickness of 6 mm is used for the analog calculation to obtain the temperature distribution, and temperature reaches 1000° C. at the bottom and 800° C. at the top. In FIG. 3B, a draft tube of FIG. 2 with an inner tube having a wall thickness of 12 mm is used for the analog calculation to obtain the temperature distribution, and temperature reaches 930° C. at the bottom and 690° C. at the top. Obviously, the inner tube of prior art with 6 mm of wall thickness has a smaller temperature gradient 0.2, but the inner tube of the present application with 12 mm of wall thickness has a larger temperature gradient 0.26. The present application benefits the heat radiation from the ingot surface to the inner tube of the draft tube.

It should be understood that, the present example describes the outer tube and the inner tube formed by the same material and the inner tube wall being thicker than the outer tube wall for the illustrative purpose only. Any situation that the outer tube has a thermal resistance larger than that of the inner tube can be applied to the present application.

### Example 2

Referring FIG. 1 and FIG. 4, the draft tube of the crystal growing furnace and the crystal growing furnace are explained hereafter. FIG. 1 illustrates a structure diagram of the crystal growing furnace in accordance with one embodiment of the present application. FIG. 4 illustrates a structure diagram of the draft tube of the crystal growing furnace in accordance with one embodiment of the present application.

Referring FIG. 1, a structure diagram of the crystal growing furnace in accordance with one embodiment of the present application is illustrated. The crystal growing furnace comprises a furnace body 1, a crucible 101 and a heater 102 disposed in the furnace body 1, wherein the heater 102 heats the crucible 101. A crucible driving device (not shown) is disposed under the crucible 101 to drive rotation and vertical movement of the crucible 101, and the direction of rotation and vertical movement is respectively indicated by the arrow A and the arrow B in FIG. 1. During the crystal pulling, a silicon melt 2 is contained in the crucible 101, and a lifting device (not shown) disposed at the top of the furnace body pulls the ingot 201 to move upward, as indicated by the arrow C in FIG. 1, to grow the crystal.

During the crystal growth, with the crystal formation of the ingot 201, the larger temperature gradient along with the axis of the ingot 201 benefits release of latent heat of the crystal. As shown in FIG. 1, a draft tube 103 is disposed surrounding the ingot 201. The draft tube 103 prevents the heat radiation from the silicon melt 2 in the crucible 101 to the ingot 201 and benefits the increase of the vertical temperature gradient of the ingot 201. Moreover, an inert gas is introduced from the upper part of the furnace body 1 to prevent oxidation of silicon melt and silicon ingot, and the draft tube is able to conduct the inert gas.

The draft tube 103 of the present application has a cone-shaped tube structure with two open terminals, and in the cone-shaped tube structure, the diameter of the bottom is smaller than that of the top. The draft tube 103 comprises an inner tube, an outer tube and a thermal insulating material sandwiched between the inner tube and the outer tube.

Referring FIG. 4, the sectional view of side wall of the draft tube in accordance with one embodiment of the present application is illustrated. The draft tube 103 comprises an inner tube 1031, an outer tube 1032 and a thermal insulating material 1033 sandwiched between the inner tube 1031 and the outer tube 1032. The outer tube 1032 has a thermal resistance larger than that of the inner tube 1031. Therefore, the outer tube 1032 having the higher thermal resistance reduces the heat transfer from the outer tube to the inner tube, thereby the temperature of the inner tube can be reduced, the heat radiation from the ingot surface to the inner tube of the draft tube can be enhanced, and the vertical temperature gradient of the ingot can be increased. At the same time, the temperature of the outer tube increases to reduce the condensation of silica vapor (SiOx) evaporated from the silicon melt surface, thereby impurity formation and dislocation defect caused by the SiOx fallen into the silicon melt can be reduced.

In one embodiment, the thermal insulating material comprises glass fiber, asbestos, rock wool, soft felt, vacuum layer and the like. In one example, the thermal insulating material is a vacuum chamber disposed between the inner tube and the outer tube to minimize the heat transfer between the outer tube and the inner tube.

In one embodiment, the inner tube and the outer tube are formed by different materials, in which the inner tube has a thermal conductivity higher than that of the outer tube. Based on the different thermal conductivity, the inner tube and the outer tube have different thermal resistances between each other, thereby the inner tube is better on heat radiation but the outer tube is not. Accordingly, the effects of temperature reduction on the inner tube and temperature increase on the outer tube can be achieved. As shown in FIG. 4, the inner tube 1031 and the outer tube 1032 are formed by different materials but have the identical thickness. The inner tube 1031 has a thermal conductivity higher than that of the outer tube 1032, so that, comparing with the outer tube 1032, the inner tube 1031 has a better thermal conduction property. Therefore, less heat is transferred from the outer tube 1032 to the inner tube 1031, the temperature of the inner tube is effectively lowered, the temperature of the inner tube can be reduced, the heat radiation from the ingot 301 surface to the inner tube 1031 is enhanced, and the axis temperature gradient of the ingot 201 is increased. At the same time, the temperature of the outer tube 1032 increases to reduce the condensation of silica vapor (SiOx) on the outer tube 1032, in which the silica vapor is evaporated from the silicon melt surface, thereby impurity formation and dislocation defect caused by the SiOx fallen from the outer tube 1032 into the silicon melt can be reduced. Moreover, because the inner tube 1031 and the outer tube 1032 have the same thickness, the strength of the draft tube can be guaranteed while the thermal conduction property is enhanced to the inner tube and reduced to the outer tube. In one embodiment, the inner tube is formed by a first graphite material and the outer tube is formed by a second graphite material or a ceramic material, in which the first graphite material has a thermal conductivity larger than that of the second graphite material or the ceramic material such as SiC ceramic.

It should be understood that, the present example describes the outer tube and the inner tube having the same thickness, the inner tube formed by graphite material and the outer tube formed by SiC ceramic material for the illustrative purpose only. Any situation that the inner tube has a thermal conductivity higher than that of the outer tube can be applied to the present application.

According to the above, the draft tube of crystal growing furnace and the crystal growing furnace of the present application can be achieved. The draft tube comprises an inner tube, an outer tube and a thermal insulating material sandwiched between the inner tube and the outer tube, wherein the outer tube has a thermal resistance higher than that of the inner tube. Accordingly, it is able to reduce the heat transfer from the outer tube to the inner tube, thereby the temperature of the inner tube can be reduced, the heat radiation from the ingot surface to the inner tube can be enhanced, and the vertical temperature gradient of the ingot can be increased. At the same time, the temperature of the outer tube increases to reduce the condensation of silica vapor (SiOx) evaporated from the silicon melt surface, thereby impurity formation and dislocation defect caused by the SiOx fallen into the silicon melt can be prevented.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. The scope of the present invention is defined by the appended claims and their equivalent scope.

What is claimed is:

1. A draft tube of a crystal growing furnace comprising an inner tube, an outer tube and a thermal insulating material sandwiched between the inner tube and the outer tube, wherein the inner tube has a thermal resistance less than that of the outer tube.

2. The draft tube of claim 1, wherein a ratio of the wall thickness of the outer tube to that of the inner tube is less than or equal to 1, and more than 0.

3. The draft tube of claim 2, wherein the ratio of the wall thickness of the outer tube to that of the inner tube is less than 1 and more than 0, and the outer tube and the inner tube are formed by the same material.

4. The draft tube of claim 2, wherein the outer tube and the inner tube are formed by a graphite material.

5. The draft tube of claim 4, wherein the inner tube has the wall thickness of 10 mm-14 mm, and the outer tube has the wall thickness of 6 mm-10 mm.

6. The draft tube of claim 2, wherein the outer tube and the inner tube are formed by different materials.

7. The draft tube of claim 5, wherein the inner tube is formed by a first graphite material and the outer tube is formed by a second graphite material or a ceramic material, wherein the second graphite material or the ceramic material has a thermal conductivity less than that of the first graphite material.

8. The draft tube of claim 1, wherein the thermal insulating material comprises glass fiber, asbestos, rock wool, soft felt or vacuum layer.

9. A crystal growing furnace comprising a draft tube as claimed in claim 1.
